(19) United States
(12) Patent Application Publication
(10) Pub. No.: US 2026/0026202 A1
(43) Pub. Date: Jan. 22, 2026

(54) DISPLAY PANEL AND ELECTRONIC DEVICE INCLUDING THE SAME

(71) Applicant: Samsung Display Co., Ltd., Yongin-si (KR)

(72) Inventors: HYUNWOO NOH, Yongin-si (KR); SOONKYEONG KWON, Yongin-si (KR); YOUNGMIN KIM, Yongin-si (KR); HYUN-SUK PARK, Yongin-si (KR); MOONJUNG BAEK, Yongin-si (KR); DAEHO LEE, Yongin-si (KR); SUJI HAN, Yongin-si (KR)

(21) Appl. No.: 19/234,003

(22) Filed: Jun. 10, 2025

(30) Foreign Application Priority Data
Jul. 17, 2024 (KR) 10-2024-0094701
Dec. 16, 2024 (KR) 10-2024-0187326

(51) Int. Cl. H10K 59/122; H10K 50/13

(52) U.S. Cl. CPC H10K 59/122; H10K 50/131

(57) ABSTRACT

A display panel including a base layer, a circuit element layer, and a light emitting element layer on the circuit element layer is provided. The light emitting element layer includes a light emitting element, a pixel defining film overlapping a non-light emitting area, and a separator on the pixel defining film, wherein the light emitting element includes a first electrode, a second electrode, and a function layer including a plurality of organic layers, the separator includes a first layer on the pixel defining film and a second layer, and an organic layer opening surrounding the separator on a plane is defined in at least one of the plurality of organic layers.

### CROSS-REFERENCE TO RELATED APPLICATIONS

This application claims priority to and the benefit of Korean Patent Application No. 10-2024-0094701, filed on Jul. 17, 2024, and Korean Patent Application No. 10-2024-0187326, filed on Dec. 16, 2024, in the Korean Intellectual Property Office, the entire disclosure of each of which are incorporated herein by reference.

### BACKGROUND

One or more aspects of embodiments of the present disclosure described herein relate to a display panel and an electronic device including the display panel. For example, a display panel and an electronic device having improved display quality.

An electronic device such as a television, a monitor, a smartphone, a tablet PC, and/or the like, which provides an image to a user, includes a display panel that displays an image. One or more suitable display panels such as liquid crystal display panels, organic light emitting display panels, electrowetting display panels, and electrophoretic display panels as display panels are being developed.

The organic light emitting display panel may include an anode, a cathode, and an organic light emitting layer.

### SUMMARY

One or more aspects of embodiments of the present disclosure are directed toward a display panel having a reduced leakage current and an electronic device including the display panel.

However, it should be noted that these objectives are merely examples, and the scope of the disclosure is not limited to the herein-mentioned aspects. Rather, other objectives of one or more embodiments of the present disclosure will be apparent to those skilled in the art from the following descriptions.

Additional aspects of one or more embodiments will be set forth in part in the description which follows and, in part, will be apparent from the description, or may be learned by practice of the presented embodiments.

According to one or more embodiments, a display panel including a base layer in which a light emitting area and a non-light emitting area around (e.g., surrounding) the light emitting area are defined, a circuit element layer on the base layer, and a light emitting element layer on the circuit element layer and including a light emitting element, a pixel defining film overlapping the non-light emitting area, and a separator on the pixel defining film, wherein the light emitting element includes a first electrode, a second electrode opposite to the first electrode, and a function layer including a plurality of organic layers and between the first electrode and the second electrode, the separator includes a first layer on the pixel defining film and a second layer on the first layer, and an organic layer opening is around (e.g., surrounding) the separator on a plane, and is defined in at least one organic layer of the plurality of organic layers.

The second electrode may be a common layer overlapping the light emitting area and the non-light emitting area.

The first layer may include a first lower surface adjacent to the pixel defining film, a first upper surface opposite to the first lower surface, and a first side surface connecting the first lower surface and the first upper surface, the second layer may include a second lower surface adjacent to the first layer, a second upper surface opposite to the second lower surface, and a second side surface connecting the second lower surface and the second upper surface, an angle between the first lower surface and the first side surface may be at most 90 degrees) (°) (e.g., or less), and an angle between the second lower surface and the second side surface may be at most 90° (e.g., or less).

An edge of the second lower surface may protrude further than an edge of (e.g., each of) the first upper surface and an edge of the first lower surface.

The organic layer opening may be around (surround) the light emitting area on a plane.

The second layer may include a second lower surface adjacent to the first layer, a second upper surface opposite to the second lower surface, and a second side surface connecting the second lower surface and the second upper surface, the function layer may cover the second upper surface and the second side surface, and the function layer may not be on (e.g., in contact with) the second lower surface.

The function layer may not be on (e.g., in contact with) the first layer and may be spaced and/or apart (e.g., spaced apart or separated) from the first layer.

The plurality of organic layers may include a first light emitting layer on the first electrode, a first charge generating layer on the first light emitting layer, and a second light emitting layer on the first charge generating layer, and the organic layer opening may be defined in the first light emitting layer and the first charge generating layer.

The second light emitting layer may be a common layer overlapping the light emitting area and the non-light emitting area.

The plurality of organic layers may include a first light emitting layer on the first electrode, a first charge generating layer on the first light emitting layer, a second light emitting layer on the first charge generating layer, a second charge generating layer on the second light emitting layer, and a third light emitting layer on the second charge generating layer, and the organic layer opening may be defined in the first light emitting layer, the first charge generating layer, the second light emitting layer, and the second charge generating layer.

The third light emitting layer may be a common layer overlapping the light emitting area and the non-light emitting area.

The first layer may include a conductive film, and the second layer may include an insulating film.

The first layer may include an indium tin oxide, an indium zinc oxide, an indium gallium zinc oxide, silver, or aluminum, and the second layer may include a silicon oxide, a silicon nitride, or a silicon oxynitride.

According to one or more embodiments, a display panel includes a base layer in which a light emitting area and a non-light emitting area around (e.g., surrounding) the light emitting area are defined, a circuit element layer on the base layer, and a light emitting element layer on the circuit element layer and including a light emitting element, a pixel defining film defining a lower opening and overlapping the non-light emitting area, and a separator on the pixel defining film, wherein the light emitting element includes a first electrode, a second electrode opposite to the first electrode, a function layer including a plurality of organic layers and between the first electrode and the second electrode, and an auxiliary electrode on the second electrode, the separator includes a first layer defining an upper opening and on the pixel defining film and a second layer on the first layer, a thickness of the first layer is greater than a sum of a thickness of the function layer, a thickness of the second electrode, and a thickness of the auxiliary electrode, the function layer, the second electrode, and the auxiliary electrode are inside the upper opening, and the auxiliary electrode covers a portion of a side surface of the first layer, which is not covered by the function layer and the second electrode.

According to one or more embodiments, an electronic device includes a display panel and a window on the display panel, wherein the display panel includes a base layer in which a light emitting area and a non-light emitting area around (e.g., surrounding) the light emitting area are defined, a circuit element layer on the base layer, and a light emitting element layer on the circuit element layer and including a light emitting element, a pixel defining film overlapping the non-light emitting area, and a separator on the pixel defining film, wherein the light emitting element includes a first electrode, a second electrode opposite to the first electrode, and a function layer including a plurality of organic layers and between the first electrode and the second electrode, the separator includes a first layer on the pixel defining film and a second layer on the first layer, and an organic layer opening around (e.g., surrounding) the separator on a plane and is defined in at least one organic layer of the plurality of organic layers.

The second electrode may be a common layer overlapping the light emitting area and the non-light emitting area.

The first layer may include a first lower surface adjacent to the pixel defining film, a first upper surface opposite to the first lower surface, and a first side surface connecting the first lower surface and the first upper surface, the second layer may include a second lower surface adjacent to the first layer, a second upper surface opposite to the second lower surface, and a second side surface connecting the second lower surface and the second upper surface, an angle between the first lower surface and the first side surface may be at most 90° (e.g., or less), and an angle between the second lower surface and the second side surface may be at most 90° (e.g., or less).

An edge of the second lower surface may protrude further than an edge of (e.g., each of) the first upper surface and an edge of the first lower surface.

The second layer may include a second lower surface adjacent to the first layer, a second upper surface opposite to the second lower surface, and a second side surface connecting the second lower surface and the second upper surface, the function layer may cover the second upper surface and the second side surface, the function layer may not be on (e.g., in contact with) the second lower surface, and the function layer may not be on (e.g., in contact with) the first layer and may be spaced and/or apart (e.g., spaced apart or separated) from the first layer.

The first layer may include an indium tin oxide, an indium zinc oxide, an indium gallium zinc oxide, silver, or aluminum, and the second layer may include a silicon oxide, a silicon nitride, or a silicon oxynitride.

### BRIEF DESCRIPTION OF THE DRAWINGS

The accompanying drawings are included to provide a further understanding of the preceding and other aspects, and features of the present disclosure and are incorporated in and constitute a part of this specification. The drawings illustrate example embodiments that will become more apparent by describing in more detail embodiments thereof with reference to the accompanying drawings. In the drawings:

FIG. 1 is a perspective view of a coupled state of an electronic device according to one or more embodiments of the present disclosure.

FIG. 2 is an exploded perspective view of the electronic device according to one or more embodiments of the present disclosure.

FIGS. 3 and 4 are cross-sectional views of the electronic device according to one or more embodiments of the present disclosure.

FIGS. 5 and 6 are cross-sectional views of portions of a display module according to one or more embodiments of the present disclosure.

FIGS. 7A-7E are cross-sectional views illustrating operations of a method of manufacturing a display panel according to one or more embodiments of the present disclosure.

FIG. 8 is a cross-sectional view of a portion of the display module according to one or more embodiments of the present disclosure.

FIG. 9 is a block diagram of the electronic device according to one or more embodiments of the present disclosure.

FIG. 10 is a schematic view of the electronic device according to one or more embodiments of the present disclosure.

### DETAILED DESCRIPTION

Reference will now be made in more detail to embodiments, examples of which are illustrated in the accompanying drawings. Because the present disclosure may be suitably modified and has one or more suitable forms, one or more embodiments thereof will be illustrated in the drawings and will be described herein in more detail. However, it should be understood that the present disclosure is not limited to a specific disclosure and includes all changes, equivalents, and substitutes included in the spirit and scope of the present disclosure. Rather, these embodiments are provided so that this disclosure will be thorough and complete, and will fully convey the scope of the present disclosure to those skilled in the art. Accordingly, the embodiments are merely described herein, by referring to the figures, to explain aspects of example embodiments of the present description.

In the present specification, the expression that a first component (or an area, a layer, a part, a portion, and/or the like) is “on”, “connected with” or “coupled to” a second component refers to that the first component is directly disposed on/connected with/coupled to the second component and/or refers to that a third component may be interposed therebetween.

In the present application, the wording “directly disposed” may refer to that there is no layer, no film, no area, no plate, and the like added between a part such as a layer, a film, an area, and a plate, and other parts. For example, the wording “directly between” may refer to that a component is between two layers or two members without using an additional member such as an adhesive member.

Throughout the description, the same reference numerals refer to the same components. Further, in the drawings, the thickness, the ratio, and the dimension of components may be exaggerated for effective description of technical contents.

Spatially relative terms, such as “beneath,” “below,” “lower,” “above,” “upper,” “bottom,” “top,” and/or the like, may be used herein for ease of description to describe one element or feature's relationship to another element(s) or feature(s) as illustrated in the drawings. It will be understood that the spatially relative terms are intended to encompass different orientations of the device in use or operation in addition to the orientation depicted in the drawings. For example, if the device in the drawings is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

Throughout the disclosure, the expression “at least one of a, b or c” indicates: only a, only b, only c; both (e.g., simultaneously) a and b; both (e.g., simultaneously) a and c; both (e.g., simultaneously) b and c; all of a, b, and c; or variations thereof. The phrase “A and/or B” is used herein to select only A, select only B, or select both A and B. The phrase “at least one of A or B” is used to select only A, select only B, or select both A and B.

The term “and/or” includes all combinations of one or more components that may be defined by associated components.

Although the terms “first”, “second”, and/or the like may be used to describe one or more suitable components, the components should not be limited by the terms. The terms are only used to distinguish one component from another component. For example, without departing from the scope of the present disclosure, a first component may be referred to as a second component, and similarly, a second component may be referred to as a first component. Singular expressions such as “a,” “an,” and “the,” include plural expressions unless clearly otherwise indicated in the context.

Also, the terms “under”, “below”, “on”, “above”, and/or the like are used to describe the correlation of components illustrated in drawings. The terms that are relative in concept are described based on a direction illustrated in drawings. In the specification, the wording “disposed on” may refer to a case in which a first member is disposed under as well as on a second member.

It will be understood that the terms “include”, “includes”, “including”, “comprise”, “comprises”, “comprising”, “have”, “has”, “having” and/or the like, as used herein specify the presence of features, numbers, steps, operations, elements, or components, described in the specification, or a combination thereof, and do not exclude in advance the presence or additional possibility of one or more other features, numbers, steps, operations, elements, or components or a combination thereof.

Unless otherwise defined, all terms (including chemical, technical terms and scientific terms) used in the present specification have the same meaning as commonly understood by those skilled in the art to which the present disclosure belongs. Furthermore, terms such as terms defined in the dictionaries commonly used should be interpreted as having a meaning consistent with the meaning in the context of the related technology and should not be interpreted in overly ideal or overly formal meanings unless explicitly defined herein.

When a certain embodiment may be implemented differently, a specific

process order may be different from the described order. For example, two consecutively described processes may be performed substantially at the same time or may be performed in an order opposite to the described order.

The term “may” will be understood to refer to “one or more embodiments of the present disclosure,” some of which include the described element and some of which exclude that element and/or include an alternate element. Similarly, alternative language such as “or” refers to “one or more embodiments of the present disclosure,” each including a corresponding listed item.

As used herein, the phrase “consisting essentially of” indicates that any additional components will not materially affect the chemical, physical, optical or electrical properties of the semiconductor film.

Hereinafter, a display panel and an electronic device according to one or more embodiments of the present disclosure will be described with reference to the accompanying drawings.

### Electronic Device

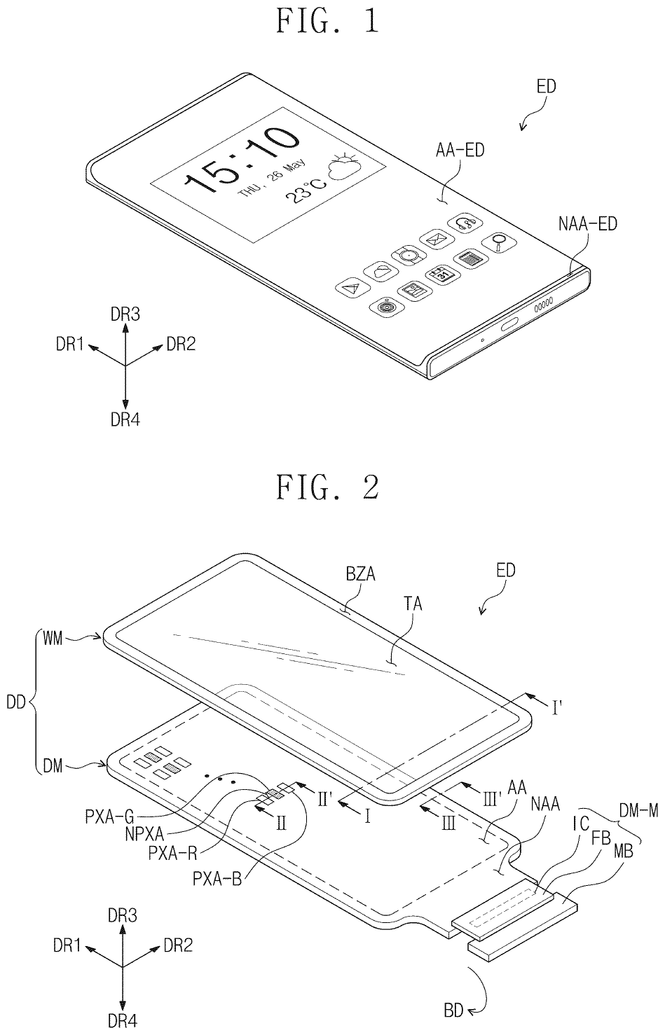

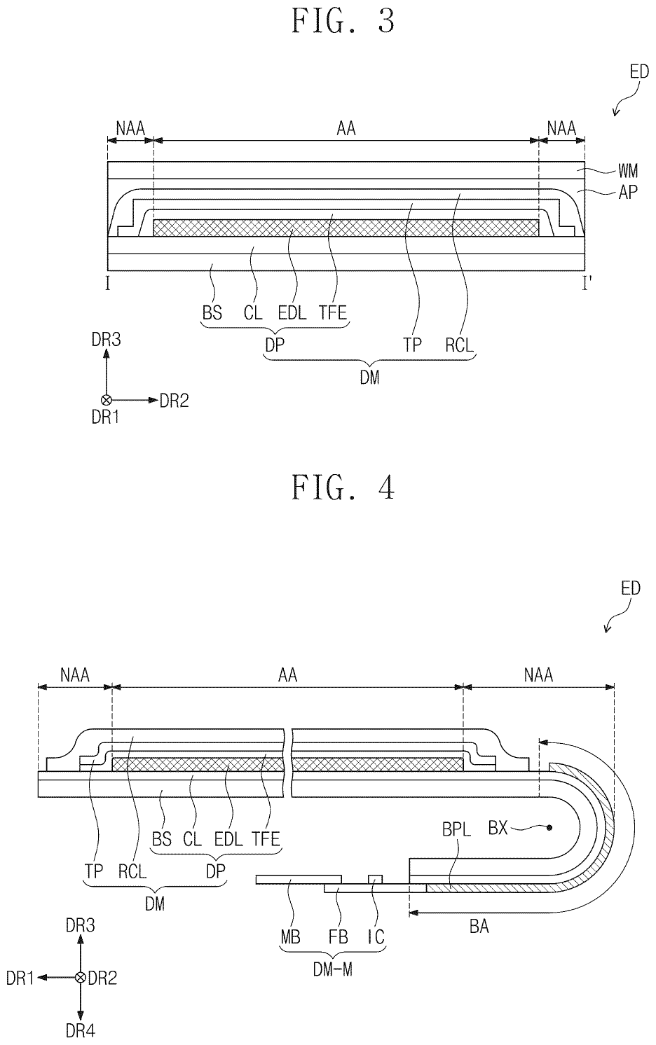

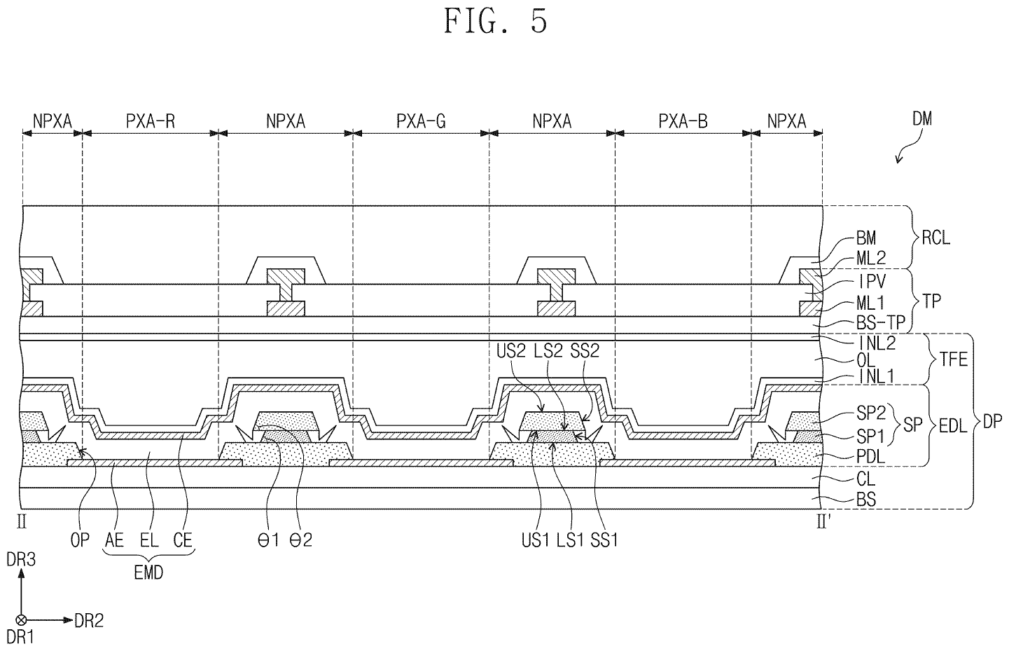

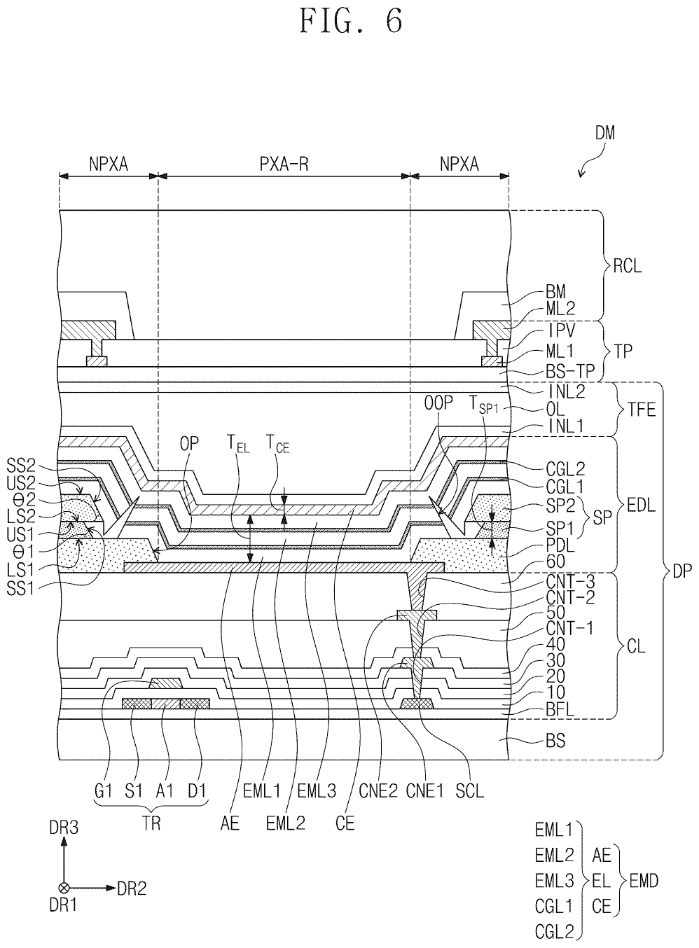

FIG. 1 is a perspective view of a coupled state of an electronic device ED according to one or more embodiments of the present disclosure. FIG. 2 is an exploded perspective view of the electronic device ED according to one or more embodiments of the present disclosure. FIGS. 3 and 4 are cross-sectional views of the electronic device ED according to one or more embodiments of the present disclosure.

The electronic device ED according to one or more embodiments of the present disclosure illustrated in FIGS. 1 to 4 may be a device that is activated according to an electrical signal. For example, the electronic device ED may be a large-sized electronic device such as a television, a monitor, and/or an external billboard. Further, the electronic device ED may be a small and medium-sized electronic device such as a personal computer, a laptop computer, a car navigation system, a game console, a smartphone, a tablet PC, a wearable device, and/or a camera. However, these are merely examples, and one or more embodiments are not limited thereto. As an example, FIG. 1 illustrates the electronic device ED as a smartphone.

The electronic device ED according to one or more embodiments may display an image through an active area AA-ED. The active area AA-ED may include a plane defined by a first direction DR1 and a second direction DR2. The active area AA-ED may further include a curved surface bent from at least one side of the plane defined by the first direction DR1 and the second direction DR2.

A peripheral area NAA-ED is adjacent to the active area AA-ED. The peripheral area NAA-ED may surround the active area AA-ED. Accordingly, a shape of the active area AA-ED may be substantially defined by the peripheral area NAA-ED. However, this is illustrated merely as an example, and the peripheral area NAA-ED may be adjacent to only one side of the active area AA-ED or may not be included (e.g., be omitted). The electronic device ED according to one or more embodiments of the present disclosure may include active areas AA-ED having one or more suitable shapes, and the present disclosure is not limited to this embodiment.

The electronic device ED according to one or more embodiments illustrated in FIG. 1 includes two curved surfaces bent from both sides (e.g., opposite sides) of the plane defined by the first direction DR1 and the second direction DR2. However, the shape of the active area AA-ED is not limited thereto. For example, the active area AA-ED may include only the plane, and the active area AA-ED may further include four curved surfaces bent from at least two, e.g., four sides of the plane.

FIG. 1 and the following drawings illustrate the first direction DR1, the second direction DR2, a third direction DR3, and a fourth direction DR4, and directions indicated by the first direction DR1, the second direction DR2, the third direction DR3, and the fourth direction DR4 described in the specification are relative concepts and may be changed to other directions.

In the specification, the first direction DR1 and the second direction DR2 are perpendicular to each other, and the third direction DR3 may be a normal direction to the plane defined by the first direction DR1 and the second direction DR2. The fourth direction DR4 may be a normal direction to the plane defined by the first direction DR1 and the second direction DR2 and may be a direction opposite to the third direction DR3.

A thickness direction of the electronic device ED may be a direction parallel to the third direction DR3 that is a normal direction to the plane defined by the first direction DR1 and the second direction DR2. In the specification, front surfaces (or upper surfaces) and rear surfaces (or lower surfaces) of members constituting the electronic device ED may be defined based on the third direction DR3.

In the specification, the wording “on a plane” may refer to a state of being viewed on a plane parallel to the plane defined by the first direction DR1 and the second direction DR2. In the specification, the wording “overlap” may refer to a state of overlapping on a plane unless otherwise defined.

Referring to FIG. 2, the electronic device ED according to one or more embodiments may include a display device DD. The display device DD may include a display module DM. The display device DD may further include a window WM on the display module DM.

The display module DM may be configured to generate an image and sense a pressure applied from the outside.

Referring to FIG. 3, the display module DM according to one or more embodiments includes a display panel DP. The display module DM according to one or more embodiments may further include a sensor layer TP on the display panel DP and an optical layer RCL on the sensor layer TP. However, the present disclosure is not limited thereto, and in one or more embodiments, the sensor layer TP or the optical layer RCL may not be included (e.g., be omitted).

An active area AA and a peripheral area NAA may be defined in the display module DM. The active area AA may be an area that is activated according to an electric signal. The peripheral area NAA may be an area located adjacent to at least one side of the active area AA.

The active area AA may correspond to the active area AA-ED of the electronic device ED illustrated in FIG. 1. The peripheral area NAA may correspond to the peripheral area NAA-ED of the electronic device ED illustrated in FIG. 1.

The active area AA may include a plurality of light emitting areas PXA-R, PXA-G, and PXA-B. For example, the electronic device ED according to one or more embodiments may include the first light emitting area PXA-R, the second light emitting area PXA-G, and the third light emitting area PXA-B. In one or more embodiments, the first light emitting area PXA-R may be a red light emitting area that emits red light, the second light emitting area PXA-G may be a green light emitting area that emits green light, and the third light emitting area PXA-B may be a blue light emitting area that emits blue light.

On a plane, the first light emitting area PXA-R, the second light emitting area PXA-G, and the third light emitting area PXA-B may be divided without overlapping each other. For example, a non-light emitting area NPXA may be between the first light emitting area PXA-R, the second light emitting area PXA-G, and the light emitting area PXA-B adjacent to each other.

As an example, FIG. 2 illustrates that the first light emitting area PXA-R, the second light emitting area PXA-G, and the third light emitting area PXA-B are provided in a stripe shape. For example, in the electronic device ED according to one or more embodiments illustrated in FIG. 2, the first light emitting area PXA-R, the second light emitting area PXA-G, and the third light emitting area PXA-B may be alternately provided in an order thereof in the second direction DR2.

The arrangement of the first light emitting area PXA-R, the second light emitting area PXA-G, and the third light emitting area PXA-B is not limited to the illustration in FIG. 2, and the order in which the first light emitting area PXA-R, the second light emitting area PXA-G, and the third light emitting area PXA-B are provided may be suitably combined and provided according to characteristics of display quality required or utilized by the electronic device ED. For example, the arrangement of the first light emitting area PXA-R, the second light emitting area PXA-G, and the third light emitting area PXA-B may be provided in a PENTILE® form or structure, (e.g., an RGBG matrix, an RGBG structure, or an RGBG matrix structure), for example, a DIAMOND PIXEL™ form or structure, e.g., a display (e.g., an OLED display) containing red, blue, and green (RGB) light emitting regions provided in the shape of diamonds. PENTILE® and DIAMOND PIXEL™ are trademarks owned by Samsung Display Co., Ltd. However, the disclosure is not limited thereto.

In one or more embodiments, the first light emitting area PXA-R, the second light emitting area PXA-G, and the third light emitting area PXA-B that emit light having different wavelengths among the first light emitting area PXA-R, the second light emitting area PXA-G, and the third light emitting area PXA-B may have different areas. In this case, the area may refer to an area when viewed on the plane defined by the first direction DR1 and the second direction DR2. However, one or more embodiments is not limited thereto, and the first light emitting area PXA-R, the second light emitting area PXA-G, and the third light emitting area PXA-B may have the same area. Further, an area ratio may be suitably adjusted according to characteristics of display quality required or utilized by the electronic device ED, and shapes of the first light emitting area PXA-R, the second light emitting area PXA-G, and the third light emitting area PXA-B may be suitably modified and provided.

FIG. 2 illustrates that the first light emitting area PXA-R, the second light emitting area PXA-G, and the third light emitting area PXA-B have a quadrangular shape on a plane, but one or more embodiments is not limited thereto, and the first light emitting area PXA-R, the second light emitting area PXA-G, and the third light emitting area PXA-B may have a shape such as a polygonal shape, a circular shape, and an elliptic shape in addition to the quadrangular shape.

The peripheral area NAA may surround the active area AA. However, one or more embodiments is not limited thereto, and unlike the illustration in FIG. 2 and the like, a portion of the peripheral area NAA may not be included (e.g., be omitted). A driving circuit or a driving wiring line for driving the active area AA may be in the peripheral area NAA.

Referring to FIG. 4, the peripheral area NAA may include a bending part BA that is bent with respect to a bending axis BX extending in one direction. A bending part protecting layer BPL may be on the bending part BA. The bending part protecting layer BPL may protect a circuit element layer CL or the like in the peripheral area NAA. The bending part protecting layer BPL may prevent cracks in components included in the circuit element layer CL or the like exposed in the bending part BA. The bending part protecting layer BPL may include at least one of an acryl-based polymer, a silicon-based polymer, and/or an imide-based polymer. However, one or more embodiments is not limited thereto.

Unlike the illustration in FIG. 4, the bending part protecting layer BPL may be connected to or overlap an edge of the optical layer RCL. Further, some of components of the optical layer RCL may extend to the bending part BA and may be provided as the bending part protecting layer BPL. Further, in one or more embodiments, the bending part protecting layer BPL may not be included (e.g., be omitted).

In one or more embodiments, the display panel DP may be a component that substantially generates an image. The display panel DP may be a light emitting display panel, and for example, the display panel DP may be an organic light emitting display panel, an inorganic light emitting display panel, a quantum dot display panel, a micro light emitting diode (LED) display panel, or a nano LED display panel. Hereinafter, it will be described that the display panel DP according to one or more embodiments is an organic light emitting display panel.

Returning to FIG. 3, is a schematic cross-sectional view corresponding to line I-I′ of FIG. 2 of the present disclosure. Referring to FIGS. 3 and 4, the display panel DP may include a base layer BS, the circuit element layer CL, a light emitting element layer EDL, and an encapsulation layer TFE.

The base layer BS may be a member that provides a base surface on which the circuit element layer CL is disposed. The base layer BS may be a rigid substrate or a flexible substrate that may be bent, folded, or rolled. The base layer BS may be a glass substrate, a metal substrate, a polymer substrate, and/or the like. However, one or more embodiments of the present disclosure is not limited thereto, and the base layer BS may be an inorganic layer, an organic layer, and/or a composite material layer.

The circuit element layer CL may be on the base layer BS. The circuit element layer CL may include an insulating layer, a semiconductor pattern, a conductive pattern, a signal line, and/or the like. The insulating layer, a semiconductor layer, and a conductive layer may be formed on the base layer BS by coating, deposition, and/or the like. Thereafter, the insulating layer, the semiconductor layer, and the conductive layer may be selectively patterned through a plurality of times of photolithography processes and etching processes. Thereafter, the semiconductor pattern, the conductive pattern, and the signal line included in the circuit element layer CL may be formed.

The light emitting element layer EDL may be on the circuit element layer CL. The light emitting element layer EDL may include a light emitting element. For example, the light emitting element may include an organic light emitting material, an inorganic light emitting material, an organic-inorganic light emitting material, a quantum dot, a quantum rod, a micro light emitting diode (LED), and/or a nano LED.

The encapsulation layer TFE may be on the light emitting element layer EDL. The encapsulation layer TFE may cover the light emitting element layer EDL. The encapsulation layer TFE may be in the active area AA in which the light emitting element layer EDL is and may be extended to the peripheral area NAA in which the light emitting element layer EDL is excluded (e.g., not included).

The encapsulation layer TFE may protect the light emitting element layer EDL from foreign substances such as moisture, oxygen, and/or dust particles.

The sensor layer TP may be on the display panel DP. The sensor layer TP may sense an external input applied from an external unit. The external input may be an input of the user. The input of the user may include one or more suitable types (kinds) of external inputs such as a portion of a body of the user, light, heat, a pen, and/or pressure.

The sensor layer TP may be formed on the display panel DP through a continuous process. In this case, the sensor layer TP may be directly on the display panel DP. Here, the wording “directly on” may refer to that a third component is not between the sensor layer TP and the display panel DP. For example, a separate adhesive member may not be between the sensor layer TP and the display panel DP. For example, the sensor layer TP may be directly on the encapsulation layer TFE of the display panel DP. The sensor layer TP may be coupled to the display panel DP through an adhesive member. The adhesive member may include a general adhesive or a pressure-sensitive adhesive.

The optical layer RCL may be on the sensor layer TP. The optical layer RCL may be directly on the sensor layer TP. The optical layer RCL may be formed on the sensor layer TP through a continuous process. The optical layer RCL may reduce reflectance by external light incident from the outside of the display module DM. The optical layer RCL may include a polarizing layer or a color filter layer. In one or more embodiments, the optical layer RCL may not be included (e.g., be omitted).

In one or more embodiments of the present disclosure, the sensor layer TP may not be included (e.g., be omitted). In this case, the optical layer RCL may be directly on the display panel DP. In one or more embodiments, positions of the sensor layer TP and the optical layer RCL may be exchanged with each other.

The electronic device ED may further include a driving unit DM-M electrically connected to the display module DM. The driving unit DM-M may be electrically connected to the display panel DP and the sensor layer TP. The driving unit DM-M may include a driving chip IC. The driving chip IC may generate or process one or more suitable electrical signals, and the driving chip IC may be electrically connected to the display panel DP, the sensor layer TP and/or the like to control the display panel DP, the sensor layer TP and/or the like.

The driving unit DM-M may include a flexible circuit board FB and a driving circuit board MB. The flexible circuit board FB may be electrically connected to the display panel DP and the sensor layer TP on one side thereof and electrically connected to the driving circuit board MB on the other side thereof. The driving chip IC may be on the flexible circuit board FB. In this case, the flexible circuit board FB may also be referred to as a Chip on Film (CoF). In one or more embodiments, the driving chip IC may be on the base layer BS of the display module DM.

FIG. 2 illustrates that the driving unit DM-M is connected to one side of the display module DM and unfolded, but as illustrated in FIG. 4, the driving unit DM-M may be bent (BD) in the fourth direction DR4 in the electronic device ED according to one or more embodiments. Referring to FIG. 4, the driving unit DM-M may be bent and may overlap the display panel DP on a plane.

The electronic device ED according to one or more embodiments may further include the window WM on the display module DM. The window WM may cover the entire outer side of the display module DM. The window WM may be coupled to the display module DM through an adhesive layer AP.

The window WM may have a shape corresponding to a shape of the display module DM. In the electronic device ED according to one or more embodiments, the window WM may include an optically transparent insulating material. The window WM may be a glass substrate and/or a polymer substrate. For example, the window WM may be a chemically reinforced glass substrate.

The window WM may be divided into a transmissive portion TA and a bezel portion BZA. The transmissive portion TA may be a portion corresponding to the active area AA of the display module DM, and the bezel portion BZA may be a portion corresponding to the peripheral area NAA of the display module DM. The bezel portion BZA may define a shape of the transmissive portion TA. The bezel portion BZA may be adjacent to the transmissive portion TA and may surround the transmissive portion TA. However, one or more embodiments are not limited to the illustration, and the bezel portion BZA may be adjacent to only one side of the transmissive portion TA or a portion thereof may not be included (e.g., be omitted).

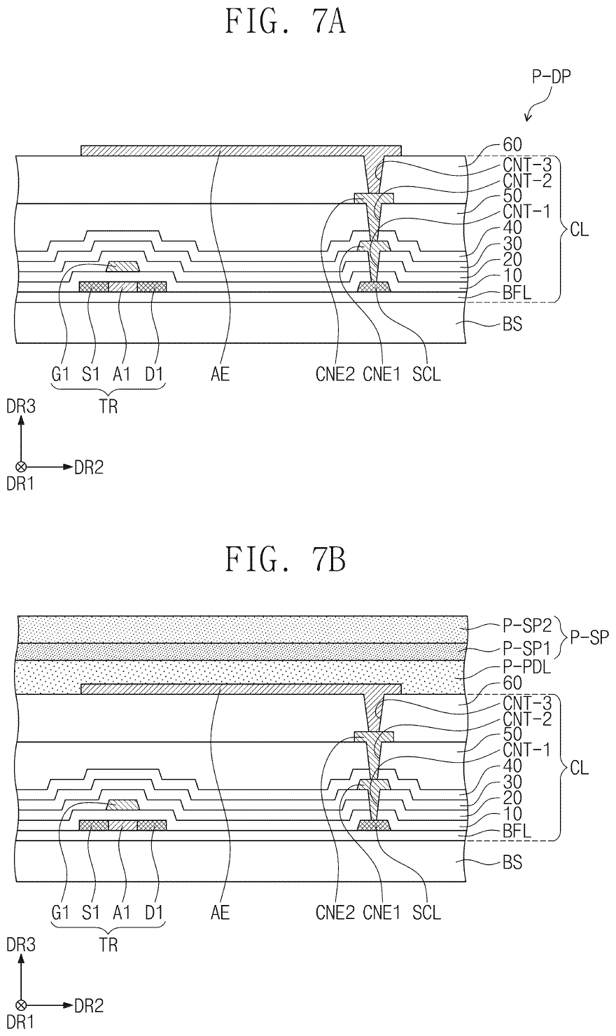

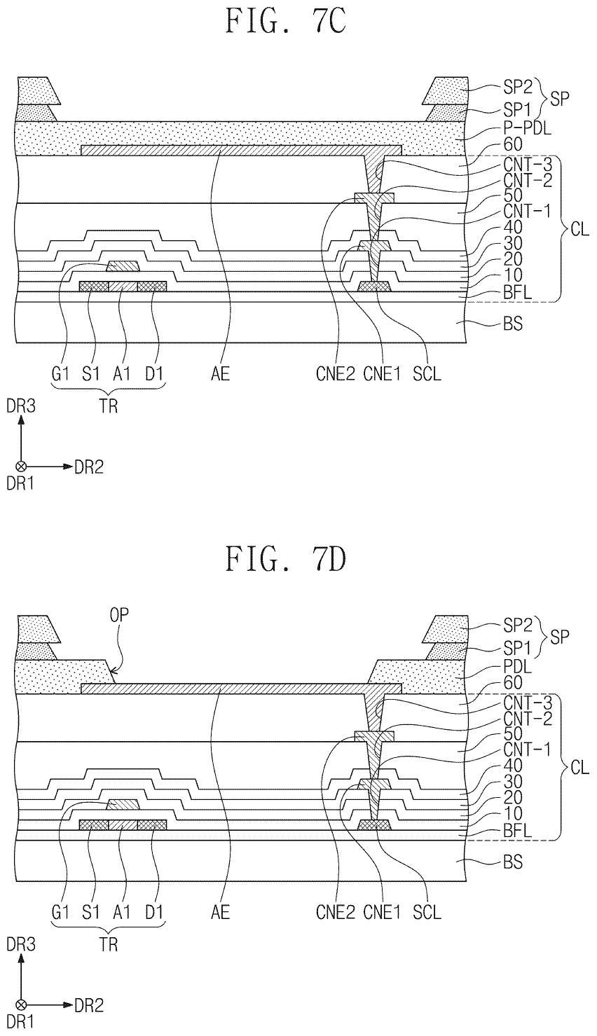

FIGS. 5 and 6 are cross-sectional views of portions of the display module DM according to one or more embodiments of the present disclosure.

FIG. 5 is a cross-sectional view corresponding to line II-II′ of FIG. 2. FIG. 5 illustrates the first light emitting area PXA-R, the second light emitting area PXA-G, the third light emitting area PXA-B, and the non-light emitting area NPXA according to one or more embodiments. FIG. 6 illustrates the first light emitting area PXA-R and the non-light emitting area NPXA according to one or more embodiments. FIG. 5 schematically illustrates the circuit element layer CL and the light emitting element layer EDL, and FIG. 6 illustrates the circuit element layer CL and the light emitting element layer EDL in detail.

Referring to FIGS. 5 and 6, the display module DM according to one or more embodiments may include the display panel DP, the sensor layer TP on the display panel DP, and the optical layer RCL on the sensor layer TP.

In one or more embodiments, the display panel DP may include the base layer BS, the circuit element layer CL, the light emitting element layer EDL, and the encapsulation layer TFE which are sequentially laminated.

The base layer BS may provide a base surface on which the circuit element layer CL, the light emitting element layer EDL, and the encapsulation layer TFE of the display panel DP are provided.

The base layer BS may be a glass substrate, a metal substrate, a polymer substrate, and/or the like. However, one or more embodiments of the present disclosure is not limited thereto, and the base layer BS may be an inorganic layer, an organic layer, and/or a composite material layer.

The base layer BS may have a single-layer or multi-layer structure. For example, when the base layer BS has a multi-layered structure, the base layer BS may have a three-layered structure of a synthetic resin layer, an adhesive layer, and a synthetic resin layer. For example, the synthetic resin layer may include a polyimide-based resin. Further, the synthetic resin layer may include at least one of an acryl-based resin, a methacryl-based resin, a polyisoprene-based resin, a vinyl-based resin, an epoxy-based resin, a urethane-based resin, a cellulose-based resin, a siloxane-based resin, a polyamide-based resin, and/or a perylene-based resin. In the specification, a “˜˜ based” resin refers to a resin containing a functional group of “˜˜”.

The circuit element layer CL is on the base layer BS. The circuit element layer CL may include a buffer layer BFL. The buffer layer BFL may improve a coupling force between the base layer BS and the semiconductor pattern. The buffer layer BFL may include at least one of a silicon oxide layer, a silicon nitride layer, and/or a silicon oxy nitride layer. For example, the buffer layer BFL may be formed by alternately laminating two or more layers selected from a silicon oxide layer, a silicon nitride layer, and a silicon oxy nitride layer.

The semiconductor pattern may be on the buffer layer BFL. The semiconductor pattern may include silicon. For example, the semiconductor pattern may include amorphous silicon, polycrystalline silicon, and/or the like. However, one or more embodiments is not limited thereto, and the semiconductor pattern may also include a metal oxide.

FIG. 6 merely illustrates a portion of the semiconductor pattern, and the semiconductor pattern may be further included in other areas. The semiconductor pattern may be in a specific rule across pixels. The semiconductor pattern may have a different electrical property depending on whether or not the semiconductor pattern is doped. The semiconductor pattern may include a first area having higher conductivity and a second area having lower conductivity. The first area may be doped with an N-type (kind) dopant or a P-type (kind) dopant. A P-type (kind) transistor may include a doped area doped with the P-type (kind) dopant, and an N-type (kind) transistor may include a doped area doped with the N-type (kind) dopant. The second area may be a non-doped area or may be an area doped at a concentration that is lower than a concentration of the first area. The second area may also be referred to as a channel area.

A conductivity of the first area is greater than a conductivity of the second area, and the first area may substantially serve as an electrode or a signal line. The second area may substantially correspond to an active area (or a channel) of a transistor. In other words, a portion of the semiconductor pattern may be an active region of the transistor, another portion thereof may be a source or drain of the transistor, and still another portion thereof may be a connection electrode or a connection signal line.

Each of the pixels may have an equivalent circuit including a plurality of transistors, one capacitor, and a light emitting element, and the equivalent circuit of the pixel may be modified in one or more suitable forms. FIG. 6 exemplarily illustrates one transistor TR and a light emitting element EMD included in the pixel.

A source area S1, an active area A1, and a drain area D1 of the transistor TR may be formed from a semiconductor pattern. The source area S1 and the drain area D1 may extend from the active area A1 in opposite directions on a cross section. FIG. 6 illustrates a portion of a connection signal line SCL formed from the semiconductor pattern. In one or more embodiments, the connection signal line SCL may be electrically connected to the drain area D1 of the transistor TR on a plane.

A first insulating layer 10 may be on the buffer layer BFL. The first insulating layer 10 may commonly overlap the plurality of pixels and cover the semiconductor pattern. The first insulating layer 10 may be an inorganic layer and/or an organic layer and may have a single-layer structure or a multi-layer structure. The first insulating layer 10 may include at least one of an aluminum oxide, a titanium oxide, a silicon oxide, a silicon nitride, a silicon oxy nitride, a zirconium oxide, and/or a hafnium oxide. In one or more embodiments, the first insulating layer 10 may be a single-layered silicon oxide layer. The first insulating layer 10 and an insulating layer of the circuit element layer CL, which will be described in more detail, may be an inorganic layer and/or an organic layer and may have a single-layer structure or a multi-layer structure. The inorganic layer may include at least one of the herein-described materials, but the present disclosure is not limited thereto.

A gate G1 of the transistor TR is on the first insulating layer 10. The gate G1 may be a portion of a metal pattern. The gate G1 overlaps the active area A1. The gate G1 may function as a mask in a process of doping the semiconductor pattern. The gate G1 may include titanium (Ti), silver (Ag), an alloy containing silver, molybdenum (Mo), an alloy containing molybdenum, aluminum (Al), an alloy containing aluminum, an aluminum nitride (AlN), tungsten (W), a tungsten nitride (WN), copper (Cu), an indium tin oxide (ITO), an indium zinc oxide (IZO) and/or the like, but the present disclosure is not particularly limited thereto.

A second insulating layer 20 may be on the first insulating layer 10 to cover the gate G1. The second insulating layer 20 may be an inorganic layer and/or an organic layer and may have a single-layer or multi-layer structure including at least one of a silicon oxide layer, a silicon nitride layer, and/or a silicon oxynitride layer.

A third insulating layer 30 may be on the second insulating layer 20 and may have a single-layer or multi-layer structure including at least one of a silicon oxide layer, a silicon nitride layer, and/or a silicon oxynitride layer.

A first connection electrode CNE1 may be on the third insulating layer 30. The first connection electrode CNE1 may be connected to the connection signal line SCL through a contact hole CNT-1 passing through the first insulating layer 10, the second insulating layer 20, and the third insulating layer 30.

A fourth insulating layer 40 may be on the third insulating layer 30. The fourth insulating layer 40 may have a single-layer or multi-layer structure including at least one of a silicon oxide layer, a silicon nitride layer, and/or a silicon oxynitride layer.

A fifth insulating layer 50 may be on the fourth insulating layer 40. The fifth insulating layer 50 may be an organic layer.

A second connection electrode CNE2 may be on the fifth insulating layer 50. The second connection electrode CNE2 may be connected to the first connection electrode CNE1 through a contact hole CNT-2 passing through the fourth insulating layer 40 and the fifth insulating layer 50.

A sixth insulating layer 60 may be on the fifth insulating layer 50 and may cover the second connection electrode CNE2. The sixth insulating layer 60 may be an organic layer.

The light emitting element layer EDL may be on the circuit element layer CL. The light emitting element layer EDL may include the light emitting element EMD including a function layer EL, and a pixel defining film PDL. The light emitting element layer EDL may further include a separator SP on the pixel defining film PDL.

The light emitting element EMD may include a first electrode AE, the function layer EL, and a second electrode CE. The function layer EL may include at least one light emitting layer EML1, EML2, and EML3. Further, the function layer EL may further include a first charge generating layer CGL1, a second charge generating layer CGL2, a hole transport area, and/or an electron transport area. The first electrode AE may be on the sixth insulating layer 60. The first electrode AE may be connected to the second connection electrode CNE2 through a contact hole CNT-3 passing through the sixth insulating layer 60. The first electrode AE may include at least one selected from among Ag, Mg, Cu, Al, Pt, Pd, Au, Ni, Nd, Ir, Cr, Li, Ca, LiF, Mo, Ti, W, In, Sn, and Zn, a compound of two or more selected therefrom, a mixture of two or more selected therefrom, or an oxide thereof.

When the first electrode AE is the transmissive electrode, the first electrode AE may include a transparent metal oxide, for example, an indium tin oxide (ITO), an indium zinc oxide (IZO), a zinc oxide (ZnO), an indium tin zinc oxide (ITZO) and/or the like.

When the first electrode AE is a semi-transmissive electrode or a reflective electrode, the first electrode AE may include Ag, Mg, Cu, Al, Pt, Pd, Au, Ni, Nd, Ir, Cr, Li, Ca, LiF/Ca (a laminated structure of LiF and Ca), LiF/Al (a laminated structure of LiF and Al), Mo, Ti, W, or a compound or mixture thereof (e.g., a mixture of Ag and Mg). Alternatively, the first electrode AE may have a multi-layer structure including a reflective film or a semi-transmissive film formed of the preceding material and a transparent conductive film formed of an indium tin oxide (ITO), an indium zinc oxide (IZO), a zinc oxide (ZnO), and/or an indium tin oxide (ITZO). For example, the first electrode AE may have a three-layer structure of ITO/Ag/ITO, but the present disclosure is not limited thereto.

The pixel defining film PDL may be on the sixth insulating layer 60 and may cover a portion of the first electrode AE. An opening OP may be defined in the pixel defining film PDL. The opening OP of the pixel defining film PDL may expose at least a portion of the first electrode AE.

In one or more embodiments, the first light emitting area PXA-R is defined to correspond to a partial area of the first electrode AE exposed by the opening OP. The non-light emitting area NPXA may be around (e.g., surround) the first light emitting area PXA-R. For example, the pixel defining film PDL may define the first light emitting area PXA-R, the second light emitting area PXA-G, and the third light emitting area PXA-B. The first light emitting area PXA-R, the second light emitting area PXA-G, and the third light emitting area PXA-B and the non-light emitting area NPXA may be distinguished by the pixel defining film PDL.

Although not illustrated, in one or more embodiments, the pixel defining film PDL may include a plurality of sub-pixel defining films laminated in a thickness direction.

In one or more embodiments, the pixel defining film PDL may include a polymer resin. For example, the pixel defining film PDL may include a polyacrylate-based resin or a polyimide-based resin. Further, the pixel defining film PDL may further include an inorganic material in addition to the polymer resin. The pixel defining film PDL may include a light absorbing material or may include a black pigment or a black dye. The pixel defining film PDL including the black pigment or the black dye may implement a black pixel defining film. Carbon black may be used as the black pigment or the black dye, but one or more embodiments is not limited thereto.

Further, the pixel defining film PDL may include an inorganic material. For example, the pixel defining film PDL may include a silicon nitride, a silicon oxide, a silicon oxy nitride, and/or the like.

The separator SP may be on the pixel defining film PDL. On a plane, the separator SP may be inside the pixel defining film PDL. On a plane, the separator SP may overlap the non-light emitting area NPXA. On a plane, the separator SP may surround the first light emitting area PXA-R, the second light emitting area PXA-G, and the third light emitting area PXA-B.

The separator SP may have a two-layer structure. The separator SP may include a first layer SP1 on the pixel defining film PDL and a second layer SP2 on the first layer SP1. The first layer SP1 may include a first lower surface LS1 adjacent to the pixel defining film PDL, a first upper surface US1 opposite to the first lower surface LS1, and a first side surface SS1 connecting the first lower surface LS1 and the first upper surface US1. The second layer SP2 may include a second lower surface LS2 adjacent to the first layer SP1, a second upper surface US2 opposite to the second lower surface LS2, and a second side surface SS2 connecting the second lower surface LS2 and the second upper surface US2.

An angle Θ1 formed between the first lower surface LS1 and the first side surface SS1 may be smaller than or equal to 90 degrees) (°). An area of the first lower surface LS1 may be greater than an area of the first upper surface US1. Accordingly, even when a width of the separator SP is reduced for a high-resolution panel, the separator SP may be stably on the pixel defining film PDL, and adhesion defects with the separator SP may be prevented.

An angle Θ2 formed between the second lower surface LS2 and the second side surface SS2 may be smaller than or equal to 90°. An area of the second lower surface LS2 may be greater than an area of the second upper surface US2. An edge of the second lower surface LS2 may protrude further than an edge of the second upper surface US2. Accordingly, the function layer EL may be formed to cover the second upper surface US2 and the second side surface SS2 and not to cover the second lower surface LS2.

On a plane, the second layer SP2 may protrude further than the first layer SP1 to form a tip structure. On a plane, an edge of the second layer SP2 may be outside an edge of the first layer SP1. In detail, on a plane, an edge of the second lower surface LS2 may protrude further than an edge of the first upper surface US1 and an edge of the first lower surface LS1. Accordingly, the function layer EL may not be on (e.g., in contact with) the first layer SP1 and may be spaced and/or apart (e.g., spaced apart or separated) from a side surface of the first layer SP1. Accordingly, an organic layer opening OOP, which will be described in more detail, may be defined in the function layer EL.

The first layer SP1 may include a conductive film. For example, the first layer SP1 may include an indium tin oxide (ITO), an indium zinc oxide (IZO), an indium gallium zinc oxide (IGZO), silver (Ag), and/or aluminum (Al).

The second layer SP2 may include an inorganic film. For example, the second layer SP2 may include a silicon oxide (SiOₓ), a silicon nitride (SiN_{y}), and/or a silicon oxy nitride (SiOₓN_{y}).

A thickness T_{SP1} of the first layer SP1 may be set to a thickness at which the organic layer opening OOP may be formed in at least a portion of the function layer EL. For example, the thickness T_{SP1} of the first layer SP1 may be differently set depending on a laminated structure, a material, a process condition, and the like of the function layer EL. For example, the thickness T_{SP1} of the first layer SP1 may be smaller than a sum of a thickness T_{EL} of the function layer EL and a thickness T_{CE} of the second electrode CE.

The function layer EL may be on the first electrode AE. The function layer EL may be provided to overlap the first light emitting area PXA-R, the second light emitting area PXA-G, the third light emitting area PXA-B, and the non-light emitting area NPXA.

The function layer EL may include a plurality of organic layers. The function layer EL may include at least one light emitting layer EML1, EML2, and EML3. FIG. 6 exemplarily illustrates that the function layer EL includes the first light emitting layer EML1, the second light emitting layer EML2, and the third light emitting layer EML3, but the function layer EL may include one, two, or four or more light emitting layers.

In one or more embodiments, the function layer EL may include the first light emitting layer EML1 on the first electrode AE, the second light emitting layer EML2 on the first light emitting layer EML1, and the third light emitting layer EML3 on the second light emitting layer EML2. One of the first light emitting layer EML1, the second light emitting layer EML2, and/or the third light emitting layer EML3 may emit light having a different color from those of the other two layers. For example, the first light emitting layer EML1 and the third light emitting layer EML3 may emit light having the same color, and the second light emitting layer EML2 may emit light having a different color from the color of the light generated by the first light emitting layer EML1. For example, the first light emitting layer EML1 and the third light emitting layer EML3 may emit blue light, and the second light emitting layer EML2 may emit green light.

When the function layer EL includes the first light emitting layer EML1, the second light emitting layer EML2, and the third light emitting layer EML3, the function layer EL may further include the first charge generating layer CGL1 and the second charge generating layer CGL2 between the light emitting layers. In one or more embodiments, the function layer EL may include the first charge generating layer CGL1 between the first light emitting layer EML1 and the second light emitting layer EML2 and the second charge generating layer CGL2 between the second light emitting layer EML2 and the third light emitting layer EML3. The first charge generating layer CGL1 may supply electrons or holes to each of the first light emitting layer EML1 and the second light emitting layer EML2, thereby improving luminous efficiency. Further, the second charge generating layer CGL2 may supply electrons or holes to each of the second light emitting layer EML2 and the third light emitting layer EML3, thereby improving luminous efficiency.

The organic layer opening OOP may be defined in at least one of the plurality of organic layers included in the function layer EL. Some of the plurality of organic layers may not be integrally formed by the separator SP of the present disclosure and may be spaced and/or apart (e.g., spaced apart or separated) from each other in a portion of the non-light emitting area NPXA adjacent to the first light emitting area PXA-R, the second light emitting area PXA-G, and the third light emitting area PXA-B. At least one layer in which the organic layer opening OOP is defined may be divided into a portion overlapping the first light emitting area PXA-R, the second light emitting area PXA-G, and the third light emitting area PXA-B and a portion overlapping the separator SP. The organic layer opening OOP may be around (e.g., surround) the separator SP on a plane. Further, the organic layer opening OOP may be around (e.g., surround) the first light emitting area PXA-R, the second light emitting area PXA-G, and the third light emitting area PXA-B on a plane.

As illustrated in FIG. 6, when the function layer EL includes the first light emitting layer EML1, the second light emitting layer EML2, and the third light emitting layer EML3 and the first charge generating layer CGL1 and the second charge generating layer CGL2, the organic layer opening OOP may be defined in at least the first light emitting layer EML1, the first charge generating layer CGL1, the second light emitting layer EML2, and the second charge generating layer CGL2. The organic layer opening OOP may be defined to extend to the third light emitting layer EML3, but the present disclosure is not limited thereto, and the third light emitting layer EML3 may be provided as a common layer.

Unlike the present disclosure, when the first charge generating layer CGL1 and the second charge generating layer CGL2 are provided as common layers across the first light emitting area PXA-R, the second light emitting area PXA-G, and the third light emitting area PXA-B and the non-light emitting area NPXA, the first charge generating layer CGL1 and the second charge generating layer CGL2 may have a strong lateral leakage current, and thus color mixing between the first light emitting area PXA-R, the second light emitting area PXA-G, and the third light emitting area PXA-B may occur, resulting in a decrease in efficiency and a decrease in a color matching rate. The first charge generating layer CGL1 and the second charge generating layer CGL2 of the present disclosure include the organic layer opening OOP between the first light emitting area PXA-R, the second light emitting area PXA-G, and the third light emitting area PXA-B and the separator SP and are not integrally connected, i.e., are unconnected or disconnected. Thus, the lateral leakage current may be prevented, the color mixing may be prevented, and thus the decrease in the efficiency and the decrease in the color matching rate may be prevented.

However, the function layer EL of the present disclosure is not limited to a structure including the first light emitting layer EML1, the second light emitting layer EML2, and the third light emitting layer EML3 and the first charge generating layer CGL1 and the second charge generating layer CGL2 and may have one or more suitable stack structures. For example, the function layer EL according to one or more embodiments may include the first light emitting layer EML1 and the second light emitting layer EML2 and the first charge generating layer CGL1. In more detail, the first light emitting layer EML1 may be on the first electrode AE, the second light emitting layer EML2 may be on the first light emitting layer EML1, and the first charge generating layer CGL1 may be between the first light emitting layer EML1 and the second light emitting layer EML2. In one or more embodiments, the first light emitting layer EML1 and the second light emitting layer EML2 may emit light having different colors. For example, the first light emitting layer EML1 may emit blue light, and the second light emitting layer EML2 may emit green light. The first charge generating layer CGL1 may supply electrons or holes to each of the first light emitting layer EML1 and the second light emitting layer EML2, thereby improving luminous efficiency. In this case, the organic layer opening OOP may be defined in at least the first light emitting layer EML1 and the first charge generating layer CGL1. The organic layer opening OOP may be defined to extend to the second light emitting layer EML2, but the present disclosure is not limited thereto, and the second light emitting layer EML2 may be provided as a common layer.

Alternatively, in one or more embodiments, the function layer EL may have the first light emitting layer EML1. The function layer EL may further include a hole transport area between the first electrode AE and the first light emitting layer EML1 and an electron transport area between the first light emitting layer EML1 and the second electrode CE. In this case, the organic layer opening OOP may be defined in at least the hole transport area. The organic layer opening OOP may be defined to extend to the first light emitting layer EML1 and/or the electron transport area, but the present disclosure is not limited thereto, and the first light emitting layer EML1 and/or the electron transport area may be provided as a common layer. For example, in general, the hole transport area, which may be a major cause of the lateral leakage current due to relatively large conductivity, may be at least unconnected or disconnected.

The second electrode CE may be on the function layer EL. The second electrode CE may have an integral shape, may extend to the first light emitting area PXA-R, the second light emitting area PXA-G, and the third light emitting area PXA-B and the non-light emitting area NPXA, and may be a common layer. The second electrode CE may be electrically connected to all the first light emitting area PXA-R, the second light emitting area PXA-G, and the third light emitting area PXA-B. Unlike the present disclosure, when the second electrode CE is patterned and a separate connection electrode is required, an aperture ratio of the light emitting area may be reduced according to arrangement of the connection electrode. In the second electrode CE of the present disclosure, arrangement of a separate connection electrode is not required, and thus the aperture ratio of the light emitting area may be improved, thereby improving a lifetime of the display panel DP.

The second electrode CE may include at least one selected from among Ag, Mg, Cu, Al, Pt, Pd, Au, Ni, Nd, Ir, Cr, Li, Ca, LiF, Mo, Ti, W, In, Sn, and Zn, a compound of two or more selected therefrom, a mixture of two or more selected therefrom, or an oxide thereof.

The second electrode CE may be a transmissive electrode, a semi-transmissive electrode, or a reflective electrode. When the second electrode CE is a transmissive electrode, the second electrode CE may be formed of a transparent metal oxide such as, for example, an indium tin oxide (ITO), an indium zinc oxide (IZO), a zinc oxide (ZnO), an indium tin oxide (ITZO), and/or the like.

When the second electrode CE is a semi-transmissive electrode or a reflective electrode, the second electrode CE may include Ag, Mg, Cu, Al, Pt, Pd, Au, Ni, Nd, Ir, Cr, Li, Ca, LiF/Ca (a laminated structure of LiF and Ca), LiF/Al (a laminated structure of LiF and Al), Mo, Ti, Yb, or W, or a compound or mixture (e.g., AgMg, AgYb, or MgYb) including the same. Alternatively, the second electrode CE may have a multi-layer structure including a reflective film or a semi-transmissive film formed of the preceding material and a transparent conductive film formed of an indium tin oxide (ITO), an indium zinc oxide (IZO), a zinc oxide (ZnO), and/or an indium tin oxide (ITZO). For example, the second electrode CE may include the herein-described metal materials, a combination of two or more metal materials selected from the herein-described metal materials, an oxide of the herein-described metal materials, or the like.

In one or more embodiments, the light emitting element layer EDL may further include a capping layer on the light emitting element EMD. The capping layer may be on the second electrode CE. The capping layer may include a single layer or a plurality of layers. In one or more embodiments, the capping layer may be an inorganic layer or an organic layer. For example, when the capping layer includes an inorganic material, the inorganic material may include an alkali metal compound such as LiF, an alkaline earth metal compound such as MgF₂, and SiOₓN_{y}, SiN_{y}, SiOₓ, and/or the like. For example, when the capping layer includes an organic material, the organic material may include α-NPD, NPB, TPD, m-MTDATA, Alq3, CuPc, TPD15 (N4,N4,N4′,N4′-tetra(biphenyl-4-yl)biphenyl-4,4′-diamine), TCTA (4,4′,4″-Tris(carbazol-9-yl)triphenylamine), and/or the like or may include an acrylate such as an epoxy resin or a methacrylate. The capping layer may function as a buffer layer for protecting the light emitting element EMD and/or the like thereunder.

An upper surface of the light emitting element layer EDL may be determined by shapes of the pixel defining film PDL and the light emitting element layer EDL. For example, the upper surface of the light emitting element layer EDL may not be flat and may have a step difference. A height of the upper surface of the light emitting element layer EDL based on the base layer BS may be different in the first light emitting area PXA-R, the second light emitting area PXA-G, and the third light emitting area PXA-B and the non-light emitting area NPXA. The step difference caused by the curved upper surface of the light emitting element layer EDL may be flattened by the encapsulation layer TFE.

The encapsulation layer TFE may be on the light emitting element layer EDL to seal the light emitting element layer EDL. The encapsulation layer TFE may be a thin film encapsulation layer. The encapsulation layer TFE may be one layer or a plurality of layers that are laminated. The encapsulation layer TFE may include at least one insulating layer.

The encapsulation layer TFE may include at least one inorganic film and/or at least one organic film. The encapsulation layer TFE may include a first inorganic layer INL1 on the light emitting element layer EDL, an organic layer OL on the first inorganic layer INL1, and a second inorganic layer INL2 on the organic layer OL.

The first inorganic layer INL1 and the second inorganic layer INL2 protect the light emitting element layer EDL from moisture and/or oxygen. The first inorganic layer INL1 and the second inorganic layer INL2 may include a silicon nitride, a silicon oxy nitride, a silicon oxide, a titanium oxide, and/or an aluminum oxide, but the present disclosure is not limited thereto.

The organic layer OL protects the light emitting element layer EDL from foreign substances such as dust particles. The organic layer OL may include an acryl-based compound, an epoxy-based compound, and/or the like. The organic layer OL may include an organic material capable of photopolymerization and is not particularly limited. Further, the organic layer OL may cover and flatten the step difference caused by the light emitting element layer EDL thereunder.

The sensor layer TP may be on the display panel DP. In one or more embodiments, the sensor layer TP may be directly on the second inorganic layer INL2. The sensor layer TP may be referred to as a sensor, an input sensing layer, or an input sensing panel. The sensor layer TP may include a sensing base layer BS-TP, a first conductive layer ML1, a sensing insulating layer IPV, and a second conductive layer ML2.

The sensing base layer BS-TP may be directly on the display panel DP. The sensing base layer BS-TP may be an inorganic layer including at least one of a silicon nitride, a silicon oxy nitride, and/or a silicon oxide. Alternatively, the sensing base layer BS-TP may be an organic layer including an epoxy-based resin, an acryl-based resin, and/or an imide-based resin. The sensing base layer BS-TP may have a single-layer structure or a multi-layer structure in which layers are laminated in the third direction DR3.

Each of the first conductive layer ML1 and the second conductive layer ML2 may have a single-layer structure or a multi-layer structure in which layers are laminated in the third direction DR3. The conductive layer having a single-layer structure may include a metal layer or a transparent conductive layer. The metal layer may include Mo, Ag, Ti, Cu, Al, or an alloy thereof. The transparent conductive layer may include a transparent conductive oxide such as an indium tin oxide (ITO), an indium zinc oxide (IZO), a zinc oxide (ZnO), a zinc peroxide (ZnO₂), and/or an indium zinc tin oxide (IZTO). The transparent conductive layer may include a conductive polymer such as poly(3,4-ethylenedioxythiophene) (PEDOT), metal nanowires, graphene, and/or the like.

The conductive layer having a multi-layer structure may include metal layers. The metal layers may have, for example, a three-layer structure of Ti/Al/Ti. The conductive layer having a multi-layer structure may include at least one metal layer and at least one transparent conductive layer.

The sensing insulating layer IPV may be between the first conductive layer ML1 and the second conductive layer ML2. The sensing insulating layer IPV may include an inorganic film. The inorganic film may include at least one of an aluminum oxide, a titanium oxide, a silicon oxide, a silicon nitride, a silicon oxy nitride, a zirconium oxide, and/or a hafnium oxide.

The sensing insulating layer IPV may include an organic film. The organic film may include at least one of an acryl-based resin, a methacryl-based resin, a polyisoprene, a vinyl-based resin, an epoxy-based resin, a urethane-based resin, a cellulose-based resin, a siloxane-based resin, a polyimide-based resin, a polyamide-based resin, and/or a phenylene-based resin.

The optical layer RCL may be on the sensor layer TP. For example, the optical layer RCL may be formed on the sensor layer TP through a continuous process. However, one or more embodiments is not limited thereto.

The optical layer RCL may be formed to include a pigment or a dye. In one or more embodiments, the optical layer RCL may include a plurality of filter parts that transmit light in different wavelength areas. The filter parts that transmit the light in different wavelength areas may be provided to respectively correspond to the first light emitting area PXA-R, the second light emitting area PXA-G, and the third light emitting area PXA-B distinguished by the non-light emitting area NPXA.

The optical layer RCL may further include a dividing layer BM. A material constituting the dividing layer BM is not particularly limited as long as the material absorbs light. The dividing layer BM is a layer having a black color, and in one or more embodiments, the dividing layer BM may include a black coloring agent. The black coloring agent may include black dye and black pigment. The black coloring agent may include carbon black, a metal such as chromium, or an oxide thereof.

The dividing layer BM may cover the second conductive layer ML2 of the sensor layer TP. The dividing layer BM may prevent reflection of external light by the second conductive layer ML2.

However, one or more embodiments is not limited thereto, and at least one of the sensor layer TP and/or the optical layer RCL may not be included (e.g., be omitted).

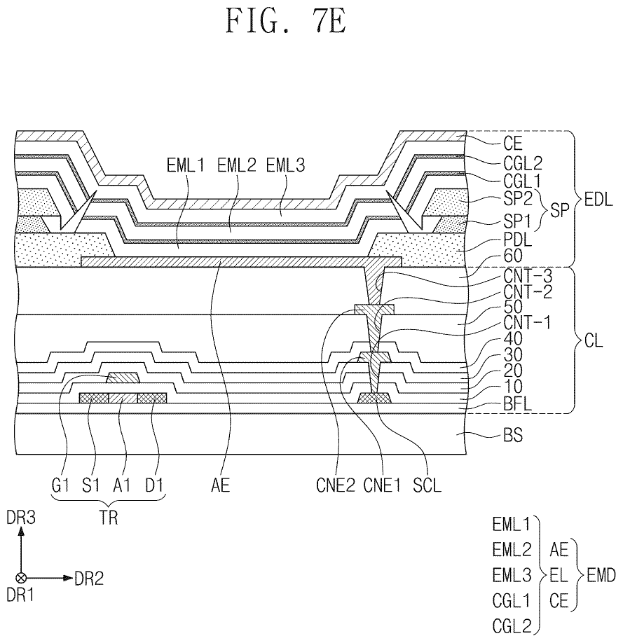

FIGS. 7A to 7E are cross-sectional views illustrating operations of a method of manufacturing a display panel according to one or more embodiments of the present disclosure.

FIGS. 7A to 7E are cross-sectional views illustrating operations of a method of manufacturing the display panel DP illustrated in FIG. 6. The preceding descriptions of FIGS. 3 to 6 may be equally applied to the components using the same reference numerals and will not be repeatedly described.

A method of manufacturing a display panel according to one or more embodiments of the present disclosure may include an operation of preparing a preliminary display panel P-DP, an operation of forming a preliminary pixel defining film P-PDL, a preliminary first layer P-SP1, and a preliminary second layer P-SP2 on the preliminary display panel P-DP, an operation of forming the separator SP, and an operation of forming the pixel defining film PDL.

Referring to FIG. 7A, the method of manufacturing a display panel according to one or more embodiments may include the operation of preparing the preliminary display panel P-DP. The preliminary display panel P-DP may include the base layer BS, the circuit element layer CL on the base layer BS, and the first electrode AE on the circuit element layer CL. The contents described with reference to FIGS. 3 to 6 may be equally applied to the base layer BS, the circuit element layer CL, and the first electrode AE.

Referring to FIG. 7B, the method of manufacturing a display panel according to one or more embodiments may include the operation of forming the preliminary pixel defining film P-PDL, the preliminary first layer P-SP1, and the preliminary second layer P-SP2 on the preliminary display panel P-DP (see FIG. 7A).

The preliminary pixel defining film P-PDL may be an inorganic film. For example, the preliminary pixel defining film P-PDL may include a silicon oxide (SiOₓ), a silicon nitride (SiN_{y}), and/or a silicon oxy nitride (SiOₓN_{y}). The preliminary pixel defining film P-PDL may be entirely deposited on the preliminary display panel P-DP (see FIG. 7A) through a plasma enhanced chemical vapor deposition (PECVD) process.

In one or more embodiments, the preliminary pixel defining film P-PDL may be an organic film. The preliminary pixel defining film P-PDL may include, for example, polyimide. The preliminary pixel defining film P-PDL may be entirely deposited on the preliminary display panel P-DP (see FIG. 7A) through a coating process. When the preliminary pixel defining film P-PDL is an organic film, after the pixel defining film PDL is formed by performing a patterning process, which will be described in more detail in FIG. 7D, the preliminary first layer P-SP1 and the preliminary second layer P-SP2 may be formed on the pixel defining film PDL. Hereinafter, a case in which the preliminary pixel defining film P-PDL is an inorganic layer will be described as an example.

The preliminary first layer P-SP1 may be a conductive film. The preliminary first layer P-SP1 may include, for example, an indium tin oxide (ITO), an indium zinc oxide (IZO), an indium gallium zinc oxide (IGZO), silver (Ag), and/or aluminum (Al). The preliminary first layer P-SP1 may be entirely deposited on the preliminary pixel defining film P-PDL through a sputtering process.

The preliminary second layer P-SP2 may be an insulating film. The preliminary second layer P-SP2 may include, for example, a silicon oxide (SiOₓ), a silicon nitride (SiN_{y}), and/or a silicon oxy nitride (SiOₓN_{y}). The preliminary second layer P-SP2 may be entirely deposited on the preliminary first layer P-SP1 through a PECVD process.

Referring to FIG. 7C, the method of manufacturing a display panel according to one or more embodiments may include the operation of forming the separator SP.

The operation of forming the separator SP may include an operation of dry-etching the preliminary second layer P-SP2 and the preliminary first layer P-SP1 and an operation of wet-etching the preliminary second layer P-SP2 and the preliminary first layer P-SP1. The operation of dry-etching the preliminary second layer P-SP2 and the preliminary first layer P-SP1 may include an operation of patterning the preliminary second layer P-SP2 and the preliminary first layer P-SP1. The operation of wet-etching the preliminary second layer P-SP2 and the preliminary first layer P-SP1 may include an operation of forming a tip structure by wet-etching the patterned preliminary second layer P-SP2 and the patterned preliminary first layer P-SP1. A tip structure in which an edge of the second layer SP2 protrudes further than an edge of the first layer SP1 may be formed using an etching solution in which an etch rate of the preliminary first layer P-SP1 is greater than an etch rate of the preliminary second layer P-SP2.

Referring to FIG. 7D, the method of manufacturing a display panel according to one or more embodiments may include the operation of forming the pixel defining film PDL.

In one or more embodiments, the pixel defining film PDL may be patterned through dry etching. The pixel defining film PDL may be patterned to define the openings OP corresponding to the first light emitting area PXA-R, the second light emitting area PXA-G, and the third light emitting area PXA-B described herein in FIGS. 5 and 6.

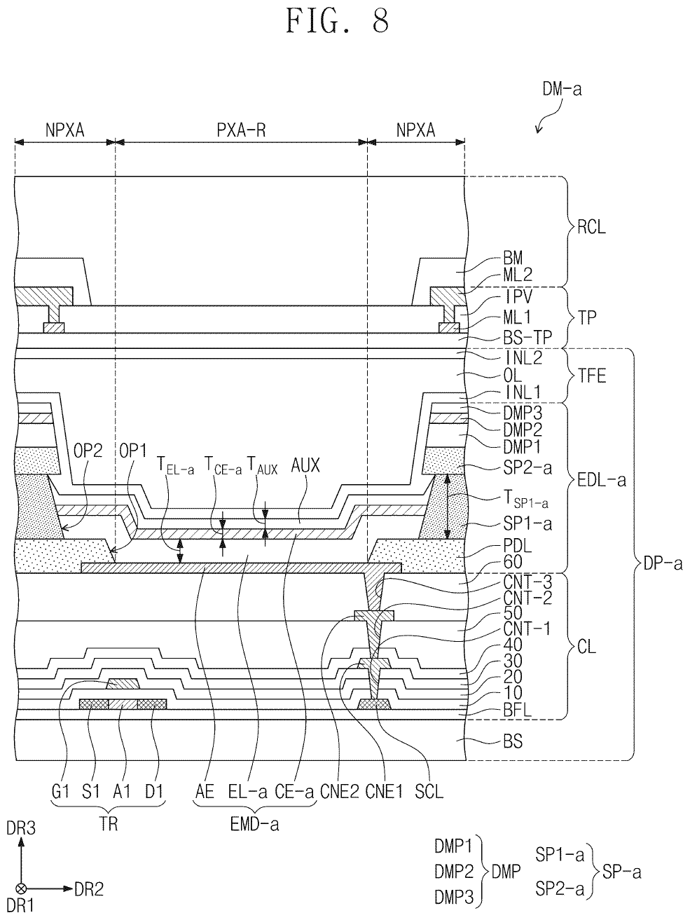

FIG. 8 is a cross-sectional view of a portion of a display module DM-a according to one or more embodiments of the present disclosure.

FIG. 8 is a cross-sectional view of the display module DM-a according to one or more embodiments in an area corresponding to FIG. 6. Except for the contents described in more detail, the contents of the display module DM described herein with reference to FIG. 6 may be applied in substantially the same manner and will not be repeatedly described.

In one or more embodiments, when a thickness T_{SP1-a} of a first layer SP1-a included in a separator SP-a is adjusted, a function layer EL-a and a second electrode CE-a may not be integrally provided in the first light emitting area PXA-R and the non-light emitting area NPXA but may be patterned inside the separator SP-a. For example, the thickness T_{SP1-a} of the first layer SP1-a may be greater than a sum of a thickness T_{EL-a} of the function layer EL-a, a thickness T_{CE-a} of the second electrode CE-a, and a thickness T_{AUX} of an auxiliary electrode AUX, which will be described in more detail.

An upper opening OP2 may be defined by a side surface of the first layer SP1-a. An opening defined by a side surface of the pixel defining film PDL may be referred to as a lower opening OP1 to be distinguished from the upper opening OP2. The lower opening OP1 may have the same configuration as the opening OP described herein in FIGS. 5 and 6.

The function layer EL-a and the second electrode CE-a may be patterned and provided inside the upper opening OP2. Accordingly, the lateral leakage current that may occur when the function layer EL-a is as a common layer may be prevented, thereby preventing the decrease in the efficiency and the decrease in the color matching rate due to the color mixing.

A dummy pattern DMP may be on a second layer SP2-a. The dummy pattern DMP may include a first dummy DMP1 on the second layer SP2-a, a second dummy DMP2 on the first dummy DMP1, and a third dummy DMP3 on the second dummy DMP2. The first dummy DMP1 may include substantially the same material as the function layer EL-a of the first light emitting area PXA-R. The second dummy DMP2 may include substantially the same material as the second electrode CE-a of the first light emitting area PXA-R. The third dummy DMP3 may include substantially the same material as the auxiliary electrode AUX of the first light emitting area PXA-R, which will be described in more detail.

Further, a light emitting element layer EDL-a according to one or more embodiments may include the auxiliary electrode AUX on the second electrode CE-a. The auxiliary electrode AUX may be inside the upper opening OP2 and may be electrically connected to the side surface of the first layer SP1-a through contact with the side surface of the first layer SP1-a. The auxiliary electrode AUX may cover the side surface of the first layer SP1-a, which is not covered by the function layer EL-a and the second electrode CE-a. Accordingly, even when the second electrode CE-a is not integrally formed in the first light emitting area PXA-R and the non-light emitting area NPXA but is patterned in the first light emitting area PXA-R, the second electrode CE-a may be electrically connected to each other. Further, the light emitting element layer EDL-a of the present disclosure may include the auxiliary electrode AUX, a connection electrode does not need to be separately in the non-light emitting area NPXA, and thus a high-resolution panel may be implemented.

The display device DD (see FIG. 2) according to one or more embodiments

of the present disclosure may be applied to one or more suitable electronic devices ED. The electronic device ED according to one or more embodiments may include the display device DD (see FIG. 2) and may further include a module or device having other additional functions in addition to the display device DD.

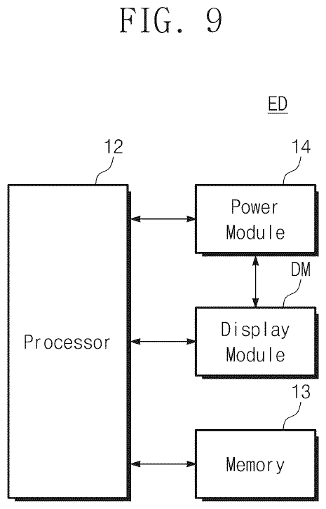

FIG. 9 is a block diagram of the electronic device ED according to one or more embodiments of the present disclosure.

Referring to FIG. 9, the electronic device ED according to one or more embodiments of the present disclosure may include the display module DM, a processor 12, a memory 13, and a power module 14.

The processor 12 may include at least one of a central processing unit (CPU), an application processor (AP), a graphic processing unit (GPU), a communication processor (CP), an image signal processor (ISP), and/or a controller.

Data information required or utilized for operations of the processor 12 or the display module DM may be stored in the memory 13. When the processor 12 executes an application stored in the memory 13, an image data signal and/or an input control signal may be transmitted to the display module DM, and the display module DM may process the received signal and output image information through the display screen.

The power module 14 may include a power supply module such as a power adapter or a battery device and a power conversion module that converts power supplied by a power supply module to generate power required or utilized for the operation of the electronic device ED.

At least one of the components of the electronic device ED may be included in the display device DD (see FIG. 2) according to one or more embodiments. Further, some of individual modules functionally included in one module may be included in the display device DD, and the others thereof may be provided separately from the display device DD (see FIG. 2). For example, the display device DD (see FIG. 2) may include the display module DM, and the processor 12, the memory 13, and power module 14 may be provided in the form of other devices inside the electronic device ED rather than the display device DD (see FIG. 2).

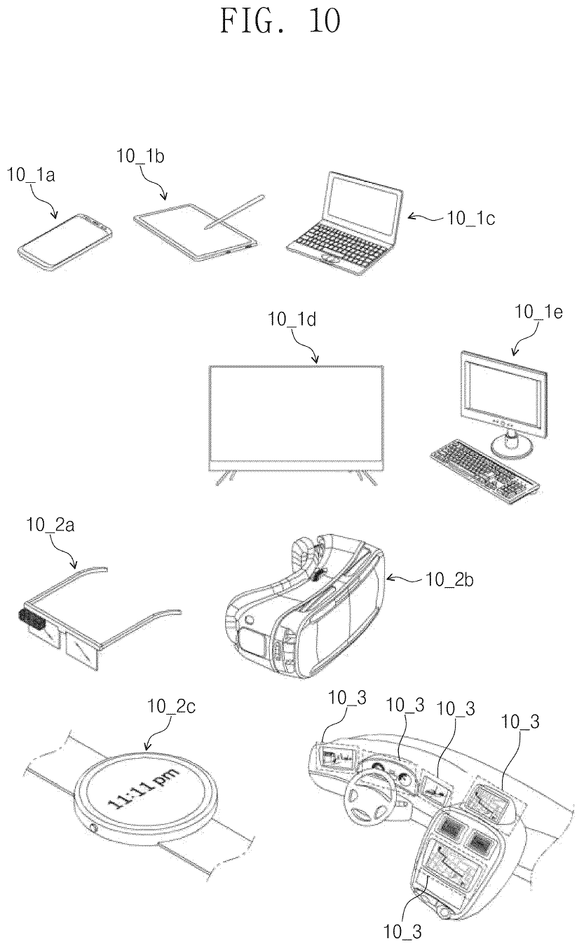

FIG. 10 is a schematic view of the electronic device ED according to one or more embodiments of the present disclosure.

Referring to FIG. 10, one or more suitable electronic devices ED, to which the display device DD (see to FIG. 2) according to one or more embodiments is applied, may include an image displaying electronic device such as a smartphone 10_1a, a tablet PC 10_1b, a laptop computer 10_1c, a television (TV) 10_1d, and a desk monitor 10_1e, a wearable electronic device including a display module such as a smart glass 10_2a, a head mounted display 10_2b, and a smart watch 10_2c, and a vehicle electronic device 10_3 including a display module such as a vehicle instrument panel, a center fascia, a center information display (CID) in a dashboard, and a room mirror display.

As described herein, a display panel according to the present disclosure may include a separator, and thus a lateral leakage current generated by a common layer included in a light emitting element may be reduced or removed. Accordingly, in the display panel according to the present disclosure, color mixing may be prevented, and thus a color matching rate, efficiency, and a lifetime thereof may be improved.

Further, in a display panel according to the present disclosure, a separate connection electrode for connecting a cathode may not be required, and accordingly, a decrease in an aperture ratio may be prevented, and the display panel may have a structure in which the separator may be stably on a pixel defining film, and thus high resolution may be implemented.

Further, an electronic device according to the present disclosure may include the herein-described display panel, and thus efficiency and a lifetime thereof may be improved, and high resolution may be implemented.

Terms such as “substantially,” “about,” and “approximately” are used as relative terms and not as terms of degree, and are intended to account for the inherent deviations in measured or calculated values that would be recognized by those of ordinary skill in the art. They may be inclusive of the stated value and an acceptable range of deviation as determined by one of ordinary skill in the art, considering the limitations and error associated with measurement of that quantity. For example, “about” may refer to one or more standard deviations, or ±30%, 20%, 10%, 5% of the stated value.

Numerical ranges disclosed herein include and are intended to disclose all subsumed sub-ranges of the same numerical precision. For example, a range of “1.0 to 10.0” includes all subranges having a minimum value equal to or greater than 1.0 and a maximum value equal to or less than 10.0, such as, for example, 2.4 to 7.6. Applicant therefore reserves the right to amend this specification, including the claims, to expressly recite any sub-range subsumed within the ranges expressly recited herein.

The display panel, electronic device, a device of manufacturing thereof, and/or any other relevant devices or components according to embodiments of the present disclosure described herein may be implemented utilizing any suitable hardware, firmware (e.g., an application-specific integrated circuit), software, or a combination of software, firmware, and hardware. For example, the one or more suitable components of the display panel and/or electronic device may be formed on one integrated circuit (IC) chip or on separate IC chips. Further, the one or more suitable components of the display panel and/or electronic device may be implemented on a flexible printed circuit film, a tape carrier package (TCP), a printed circuit board (PCB), or formed on one substrate. Further, the one or more suitable components of the display panel and/or electronic device may be a process or thread, running on one or more processors, in one or more computing devices, executing computer program instructions and interacting with other system components for performing the one or more suitable functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, and/or the like. Also, a person of skill in the art should recognize that the functionality of one or more suitable computing devices may be combined or integrated into a single computing device, or the functionality of a particular computing device may be distributed across one or more other computing devices without departing from the scope of the embodiments of the present disclosure.

In the context of the present application and unless otherwise defined, the terms “use,” “using,” and “used” may be considered synonymous with the terms “utilize,” “utilizing,” and “utilized,” respectively.

A person of ordinary skill in the art, in view of the present disclosure in its entirety, would appreciate that each suitable feature of the one or more suitable embodiments of the present disclosure may be combined or combined with each other, partially or entirely, and may be technically interlocked and operated in one or more suitable ways, and each embodiment may be implemented independently of each other or in conjunction with each other in any suitable manner unless otherwise stated or implied.

Although the description has been made preceding herein with reference to one or more embodiments of the present disclosure, it may be understood that those skilled in the art or those having ordinary knowledge in the art may suitably modify and change the present disclosure without departing from the spirit and technical scope of the present disclosure described in the appended claims and equivalents thereof.

What is claimed is:

1. A display panel comprising:
a base layer comprising:
a light emitting area; and
a non-light emitting area around the light emitting area,
a circuit element layer on the base layer; and
a light emitting element layer on the circuit element layer and comprising:
a light emitting element;
a pixel defining film overlapping the non-light emitting area; and
a separator on the pixel defining film,
wherein the light emitting element comprises:
a first electrode;
a second electrode opposite to the first electrode; and
a function layer comprising a plurality of organic layers, and being between the first electrode and the second electrode,
wherein the separator includes:
a first layer on the pixel defining film; and
a second layer on the first layer, and
wherein an organic layer opening is around the separator on a plane and is in at least one organic layer of the plurality of organic layers.

2. The display panel of claim 1, wherein the second electrode is a common layer overlapping the light emitting area and the non-light emitting area.

3. The display panel of claim 1, wherein the first layer comprises:
a first lower surface adjacent to the pixel defining film;
a first upper surface opposite to the first lower surface; and
a first side surface connecting the first lower surface and the first upper surface,
wherein the second layer comprises:
a second lower surface adjacent to the first layer;
a second upper surface opposite to the second lower surface; and
a second side surface connecting the second lower surface and the second upper surface,
wherein an angle between the first lower surface and the first side surface is at most 90 degrees (°), and
wherein an angle between the second lower surface and the second side surface is at most 90°.

4. The display panel of claim 3, wherein an edge of the second lower surface protrudes further than each of an edge of the first upper surface and an edge of the first lower surface.

5. The display panel of claim 1, wherein the organic layer opening is around the light emitting area on a plane.

6. The display panel of claim 1, wherein the second layer comprises:
a second lower surface adjacent to the first layer;
a second upper surface opposite to the second lower surface; and
a second side surface connecting the second lower surface and the second upper surface,
wherein the function layer covers the second upper surface and the second side surface, and
wherein the function layer is not on the second lower surface.

7. The display panel of claim 1, wherein the function layer is not on the first layer and is spaced apart from the first layer.

8. The display panel of claim 1, wherein the plurality of organic layers comprises:
a first light emitting layer on the first electrode;
a first charge generating layer on the first light emitting layer; and
a second light emitting layer on the first charge generating layer, and
wherein the organic layer opening is in the first light emitting layer and the first charge generating layer.

9. The display panel of claim 8, wherein the second light emitting layer is a common layer overlapping the light emitting area and the non-light emitting area.

10. The display panel of claim 1, wherein the plurality of organic layers comprises:
a first light emitting layer on the first electrode;
a first charge generating layer on the first light emitting layer;
a second light emitting layer on the first charge generating layer;
a second charge generating layer on the second light emitting layer; and
a third light emitting layer on the second charge generating layer, and
wherein the organic layer opening is in the first light emitting layer, the first charge generating layer, the second light emitting layer, and the second charge generating layer.

11. The display panel of claim 10, wherein the third light emitting layer is a common layer overlapping the light emitting area and the non-light emitting area.

12. The display panel of claim 1, wherein the first layer comprises a conductive film, and
wherein the second layer comprises an insulating film.

13. The display panel of claim 1, wherein the first layer comprises an indium tin oxide, an indium zinc oxide, an indium gallium zinc oxide, silver, or aluminum, and
wherein the second layer comprises a silicon oxide, a silicon nitride, or a silicon oxynitride.

14. A display panel comprising:
a base layer comprising:
a light emitting area; and
a non-light emitting area around the light emitting area,
a circuit element layer on the base layer; and
a light emitting element layer on the circuit element layer and comprising:
a light emitting element:
a pixel defining film comprising a lower opening and overlapping the non-light emitting area; and
a separator on the pixel defining film,
wherein the light emitting element comprises:
a first electrode;
a second electrode opposite to the first electrode;
a function layer including a plurality of organic layers, and being between the first electrode and the second electrode; and
an auxiliary electrode on the second electrode,
wherein the separator includes:
a first layer comprising an upper opening and on the pixel defining film; and
a second layer on the first layer,
wherein a thickness of the first layer is greater than a sum of a thickness of the function layer, a thickness of the second electrode, and a thickness of the auxiliary electrode,
wherein the function layer, the second electrode, and the auxiliary electrode are inside the upper opening, and
wherein the auxiliary electrode covers a portion of a side surface of the first layer, which is not covered by the function layer and the second electrode.

15. An electronic device comprising:
a display panel; and
a window on the display panel,
wherein the display panel comprises:
a base layer comprising:
a light emitting area; and
a non-light emitting area around the light emitting area;
a circuit element layer on the base layer; and
a light emitting element layer on the circuit element layer and comprising:
a light emitting element;
a pixel defining film overlapping the non-light emitting area; and
a separator on the pixel defining film,
wherein the light emitting element comprises:
a first electrode;
a second electrode opposite to the first electrode; and
a function layer comprising a plurality of organic layers, and being between the first electrode and the second electrode,
wherein the separator includes:
a first layer on the pixel defining film; and
a second layer on the first layer, and
wherein an organic layer opening is around the separator on a plane and is in at least one organic layer of the plurality of organic layers.

16. The electronic device of claim 15, wherein the second electrode is a common layer overlapping the light emitting area and the non-light emitting area.

17. The electronic device of claim 15, wherein the first layer comprises:
a first lower surface adjacent to the pixel defining film;
a first upper surface opposite to the first lower surface; and
a first side surface connecting the first lower surface and the first upper surface,
wherein the second layer comprises:
a second lower surface adjacent to the first layer;
a second upper surface opposite to the second lower surface; and
a second side surface connecting the second lower surface and the second upper surface,
wherein an angle between the first lower surface and the first side surface is at most 90°, and
wherein an angle between the second lower surface and the second side surface is at most 90°.

18. The electronic device of claim 17, wherein an edge of the second lower surface protrudes further than each of an edge of the first upper surface and an edge of the first lower surface.

19. The electronic device of claim 15, wherein the second layer comprises:
a second lower surface adjacent to the first layer;
a second upper surface opposite to the second lower surface; and
a second side surface connecting the second lower surface and the second upper surface,
wherein the function layer covers the second upper surface and the second side surface,
wherein the function layer is not on the second lower surface, and
wherein the function layer is not on the first layer and spaced apart from the first layer.

20. The electronic device of claim 15, wherein the first layer comprises an indium tin oxide, an indium zinc oxide, an indium gallium zinc oxide, silver, or aluminum, and
wherein the second layer comprises a silicon oxide, a silicon nitride, or a silicon oxynitride.
